(19) United States
(12) Patent Application Publication
(10) Pub. No.: US 2004/0258246 A1
(43) Pub. Date: Dec. 23, 2004

(54) Bass frequency amplifying apparatus

(76) Inventor: Loic Bernard Tanghe, Leuven (BE)

Correspondence Address: U.S. Philips Corporation, Intellectual Property Department, P O Box 3001, Briarcliff Manor, NY, 10510, US

(21) Appl. No.: 10/492,583

(22) PCT Filed: Oct. 14, 2002
(86) PCT No.: PCT/IB02/04230

(30) Foreign Application Priority Data
Oct. 17, 2001 (EP) 01203972.3

(51) Int. Cl. H04R 5/00; H03G 7/00

(52) U.S. Cl. 381/1; 381/106

(57) ABSTRACT

The invention relates to an apparatus (1) for amplifying bass frequencies of an audio signal (AL, AR). The bass components are applied to a controllable amplifier (17).

A comparison circuit (19) compares the signals from the output and the input of the amplifier (17). When the feed-forward signal has a larger level than the feedback signal, the bass power is decreased, or increased in the opposite case. Oscillation peak values are reduced with respect to time and frequency for flat loudspeakers.

The invention relates to an apparatus for amplifying bass frequencies of an audio signal, the apparatus comprising first means for splitting up the audio signal into a first signal portion and a second signal portion, an amplifier comprising a peak-value compressor with a controllable amplifier circuit and a control circuit for compressing the second signal portion, and second means for combining the first signal portion and the compressed second signal portion.

Such an apparatus is known from U.S. Pat. No. 6,359,655. This apparatus comprises an amplifier which is feedback-controllable and whose gain varies in dependence upon bass components. At a low level, the gain of the bass signals is higher and at a high level, it is lower. This type of bass gain is adequate to achieve good acoustics via electrodynamic loudspeakers with a conical loudspeaker membrane.

For a sound reproduction via flat loudspeakers, this kind of bass gain is not suitable. Flat loudspeakers have a flat radiation plane, hereinafter also referred to as panel, and are also known as distributed mode speakers. For esthetical reasons, flat loudspeakers are more and more widely used. The bass reproduction can be less and less realized with flat loudspeakers. In accordance with the mechanical construction, an oscillation of a flat loudspeaker is limited as compared to an electrodynamic loudspeaker with a conical membrane. A gain of the bass frequencies by electric means can rapidly lead to a distortion, particularly to a mechanical clipping and an acoustical disturbance, often before an electric clipping by the amplifier takes place.

It is therefore an object of the invention to provide an amplifier for flat loudspeakers.

This object is achieved by the characteristic features defined in claim 1. According to the invention, the peak-value compressor comprises a comparison circuit with a feed-forward loop segment connected to an input and a feedback loop segment connected to an output of the peak-value compressor. The feed-forward loop segment is part of a feed-forward control preventing a signal having a fatal peak value from being applied to the amplifier and then passed on to the loudspeaker. In this way, a feed-forward, bass-compressing audio system and method are realized, enhancing the bass power output and simultaneously preventing noticeable disturbances such as mechanical clipping of the loudspeaker. The average value of the bass signal is maximized range-wise both in time and in frequency. The idea is to add bass signals to the flat loudspeakers, which signals maximize the noticeable sound while oscillation peak values with respect to time and frequency for flat loudspeakers are prevented simultaneously.

Advantageously, the comparison circuit impresses input values from the feed-forward loop segment with a factor of 0.3-0.7, advantageously 0.4-0.6 and particularly a factor of 0.5. When a peak value detected in the feed-forward control is amplified by a factor of 0.5, which corresponds to a compression rate of 50%, the volume control can be switched more than 3 dB higher in comparison with a switched-off peak value compression. The volume control is also dependent on the decay time of the gain control in the peak-value compressor, which decay time will hereinafter also be referred to as dying-down time.

Advantageously, the first means comprise a bandpass filter for splitting up the audio signal. The peak-value compressor can operate correctly with band-limited signals. It is therefore not necessary to blow up frequencies, particularly lower frequencies, which the loudspeaker cannot reproduce.

Advantageously, the first means comprise an adder circuit for splitting up the audio signal. When frequencies are amplified which are below the resonance frequency of the loudspeaker, i.e. frequencies whose source cannot be located by a listener, bass frequencies from two or more channels can be combined in one or more adder circuits, processed by a single compressor and reproduced via one or more loudspeakers.

While the bass signals are processed, the signals which are present on the direct path can be filtered by a freely selectable high-pass filter above the resonance frequency of the loudspeaker. For this reason, only the individually processed, minimized oscillation peak values of the bass signal are applied to the loudspeaker.

Advantageously, the amplifier has an automatic gain control. The gain control checks the output level of the audio arrangement and reduces the power in the bass path when the checked levels are above a defined target level. This prevents mechanical clipping at very high output levels. The output levels are the levels which result after the addition of the first and the second compressed signal portion and after the manually controllable volume control.

These and other aspects of the invention are apparent from and will be elucidated with reference to the embodiments described hereinafter.

In the drawings:

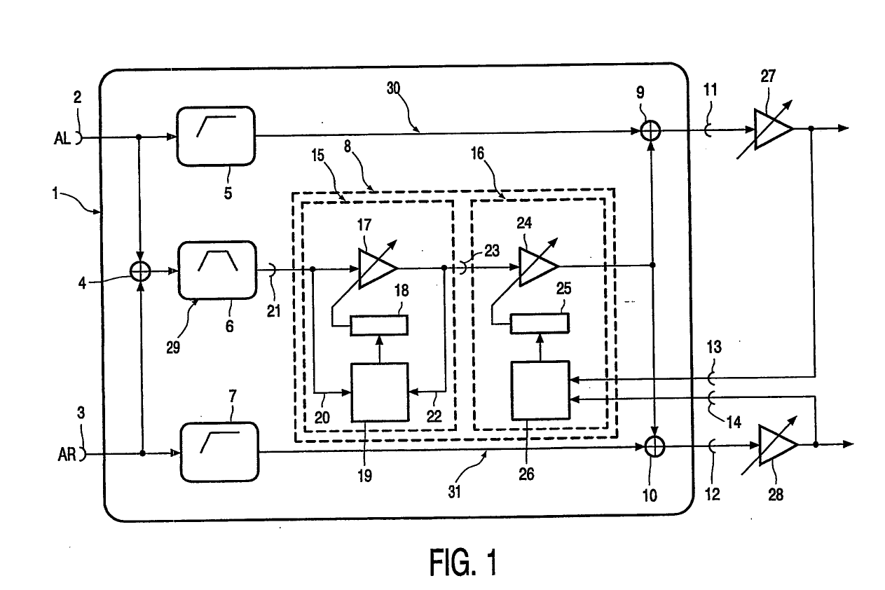

FIG. 1 is a block diagram of an apparatus for amplifying bass frequencies with a peak-value compressor, and

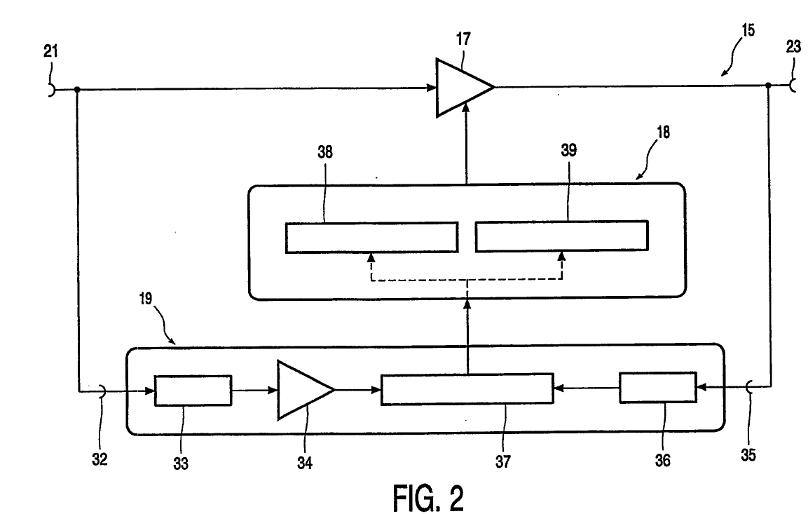

FIG. 2 is a circuit diagram of the peak-value compressor.

FIG. 1 shows an apparatus 1 for amplifying bass frequencies, the apparatus comprising two inputs 2 and 3, an adder 4, a high-pass filter 5, a bandpass filter 6, a second high-pass filter 7, an amplifier 8, two further adders 9 and 10, two outputs 11 and 12 and two further inputs 13 and 14. The amplifier 8 comprises a peak-value compressor 15 and an automatic gain control 16. The peak-value compressor 15 comprises a controllable amplifier circuit 17, a control circuit 18 and a comparator 19. A feed-forward loop segment 20 connects an input 21 of the controllable amplifier 17 to the comparator 19, and a feedback loop segment 22 connects an output 23 of the controllable amplifier 17 to the comparator 19. The automatic gain control 16 comprises a further controllable amplifier circuit 24, a further control circuit 25 and a second comparator 26. Two manually operable volume controls 27 and 28 applying signals to loudspeakers (not shown) are connected to the outputs 11 and 12. The outputs of the volume controls 27 and 28 are connected to the inputs 13 and 14 which control the second comparator 26 by means of electrically conducting connections.

The apparatus has the following function. Two digital audio signals AL and AR of a stereo system with a left and a right channel are applied to the inputs 2 and 3 of the apparatus 1. Both audio signals AL and AR are applied to the adder 4, summed, and a summed signal is band-limited in the bandpass filter 6. The apparatus 1 has a singular bass path 29 comprising the bandpass filter 6, the feed-forward peak-value compressor 15 which compresses the peak values of the amplitude of the bass signal, and the automatic gain control 16 which reduces values when the output levels are too high. The bandpass filter 6 is an IIR filter with an infinite impulse response (IIR). The peak-value compressor 15 stabilizes the peak values of the signal, while simultaneously the tail of the pulse is protected or maintained. The adder 4, which adds the signals of the left and the right channel, is connected to the input of the bass path 29. The output signal of the bass path 29 is directly added to the high-pass filtered signals of a left and a right path 30 and 31.

FIG. 2 shows the peak-value compressor 15 with the controllable amplifier circuit 17, a control circuit 18 and a comparator 19. The input 32 of the comparator 19, connected to the feed-forward loop segment 20, comprises a level detection circuit 33. The circuit 33 detects the largest signal peak value by feed-forward control with a very short reaction time of 0.1 ms and a very long decay time of 3 seconds. The level detection circuit 33, hereinafter also referred to as filter, receives a digital input signal x of an n value and the detection circuit 33 supplies a digital signal y of an n value, which can be computed with constants Ta and Tr as follows:

y(n)=|x(n)|+Kp*(y(n−1)−|x(n)|)+Km*|(y(n−1)−|x(n)|)|with

Kp=(Kr+Ka)/2

Km=(Kr−Ka)/2

Kr=exp(−1/(Tr*sample frequency))

Ka=exp(−1/(Ta*sample frequency))

The absolute value of the input signal is thus applied to a first-order access and release filter 33. With a short building-up time Ta and a longer dying-down time Tr, the peak value of the input signals x(n) is present with the signal y(n) at the output of the filter 33. The sample frequency is defined by the time interval between the occurrence of the two consecutive samples.

The level detection circuit 33 is followed by an amplifier 34. The amplifier 34 amplifies the input signal y(n) by a factor of 0.3-0.7, advantageously by 0.4-0.6 and particularly by a factor of 0.5. A further level detection circuit 36 is connected to a further input 35 facing the feedback loop segment 22. The function of this level detection circuit 36 is the same as has been elucidated with respect to the level detection circuit 33. The level detection circuit 33 supplies signals via the amplifier 34 and the level detection circuit 36 supplies signals directly to a comparison circuit 37. The comparison circuit 37 applies an output signal to the control circuit 18 comprising a gain-decreasing circuit 38 and a gain-increasing circuit 39. The circuits 33, 39 operate as follows.

In the comparison circuit 37, the filter response reduced by 50% of the filter 33 is compared with the filter response of the filter 36. When the value reduced by 50% is larger than the filter response from the feedback loop of the filter 36, the gain of the amplifier is reduced by the constant DEC_GAIN in the gain-decreasing circuit 38. When the value is larger, the gain of the amplifier 17 is increased by the constant INC_GAIN in the gain-increasing circuit 39. Limit values for the gain factor are 1.0 and 0.01.

Gain=gain*INC_GAIN

Gain=gain*DEC_GAIN

with

INC_GAIN=10exp(24/(building-up time*sample frequency*20))

DEC_GAIN=10exp(−24/(dying-down time*sample frequency*20))

The 50% reduced filter response of the filter 33 becomes a target level. This target level is compared with the peak value detected by the feedback, and the control circuit 18 adjusts the gain which is used at the output for fixing the target level with a very short dying-down time of 20 ms so as to eliminate the interventions by the input signal very rapidly. The rise time of 50 ms takes longer so as to obtain the time frame for the overall duration of the signal intervention, irrespective of which the signal is attenuated. The compressor 15 establishes the peak values of the signals independently of the volume control and without adding unwanted interference. The sound is maintained purely natural and is free from artefacts, i.e. from unwanted noticeable disturbances. While the level detection is forward controlled, the peak-value compression only depends on the input signals AL and AR. High peak-value compression rates which are lower than the 0.5-fold value of the peak-value level detected from the forward control can be achieved with this apparatus.

As the oscillation of the conical loudspeaker membrane, or the panel, is significant in this case, the oscillation curve is to be considered in proportion to the frequency. This proportion is determined by loudspeaker characteristics such as the Small and Thiele parameters. The possible bass increase can be derived from the curve and the pressure response of the loudspeaker, which bass increase maximizes the bass frequency pressure response while the maximum is not increased in the oscillation curve.

With a gain in the bandpass filter 6, more noticeable bass frequencies can be achieved, while only bass frequency peaks are reduced.

List of numerals

1 bass frequency amplifier apparatus

2 input

3 input

4 adder

5 high-pass filter

6 bandpass filter

7 high-pass filter

8 amplifier

9 adder

10 adder

11 output

12 output

13 input

14 input

15 peak-value compressor

16 automatic gain control

17 amplifier circuit

18 control circuit

19 comparator

20 feed-forward loop segment

21 input

22 feedback loop segment

23 output

24 amplifier circuit

25 control circuit

26 comparator

27 volume control

28 volume control

29 bass path

30 path

31 path

32 input

33 level detection circuit

34 amplifier

35 input

36 level detection circuit

37 comparison circuit

38 gain-decreasing circuit

39 gain-increasing circuit

1. An apparatus (1) for amplifying bass frequencies of an audio signal (AL, AR), the apparatus comprising first means (4, 5, 6 and 7) for splitting up the audio signal (AL, AR) into a first signal portion and a second signal portion, an amplifier (8) comprising a peak-value compressor (15) with a controllable amplifier circuit (17), and a control circuit (18) for compressing the second signal portion, and second means (9, 10) for combining the first signal portion and the compressed second signal portion, characterized in that the peak-value compressor (15) comprises a comparison circuit (19) with a feed-forward loop segment (20) connected to an input (21) and a feedback loop segment (22) connected to an output (23) of the peak-value compressor (15).

2. An apparatus as claimed in claim 1, characterized in that the comparison circuit (19) impresses input values from the input (22) by a factor of 0.3-0.7, advantageously 0.4-0.6 and particularly a factor of 0.5.

3. An apparatus as claimed in claim 1, characterized in that the first means (4, 5, 6 and 7) comprise a bandpass filter (6) for splitting up the audio signal (AL, AR).

4. An apparatus as claimed in claim 1 characterized in that the first means (4, 5, 6 and 7) comprise an adder circuit (4) for splitting up the audio signal (AL, AR).

5. An apparatus as claimed in claim 1 characterized in that the amplifier (8) has an automatic gain control (16).

6. A method of amplifying bass frequencies of a left and a right digital audio signal (AL, AR) of a stereo system with a left and a right channel, the method comprising the steps of:
bandpass-limiting the audio signal (AL, AR),
subsequently compressing the bandpass-limited audio signal in a feed-forward and feedback peak-value compressor,
high-pass filtering the audio signal (AL, AR), and
adding the compressed audio signal to the high-pass filtered audio signal.

7. A method as claimed in claim 6, characterized in that the left and the right audio signal are added before the bandpass limitation, and the added signal is added to the respective high-pass filtered audio signal after the compression.
